(19) United States
(12) Patent Application Publication
(10) Pub. No.: US 2026/0344407 A1
(43) Pub. Date: Oct. 29, 2026

(54) SEMICONDUCTOR DEVICE INCLUDING WIRING PATTERN

(71) Applicant: Samsung Electronics Co., Ltd., Suwon-si (KR)

(72) Inventors: Wan Su Song, Suwon-si (KR); Dong Hoon Kwon, Suwon-si (KR)

(73) Assignee: Samsung Electronics Co., Ltd., Suwon-si (KR)

(21) Appl. No.: 19/410,601

(22) Filed: Dec. 5, 2025

(30) Foreign Application Priority Data
Apr. 24, 2025 (KR) 10-2025-0053462

(51) Int. Cl. H10W 20/41; H10W 20/00; H10W 20/40; H10W 20/42; H10W 20/43; H10W 20/44

(52) U.S. Cl. CPC H10W 20/435; H10W 20/42; H10W 20/43; H10W 20/4446; H10W 20/498; H10W 20/056; H10W 20/063

(57) ABSTRACT

A semiconductor device includes a lower interlayer insulating layer, a first contact trench formed in the lower interlayer insulating layer, a first contact disposed in the first contact trench, a first conductive layer disposed on an upper surface of the first contact, a width of the first conductive layer in a first horizontal direction greater than a width of the first contact trench in the first horizontal direction, the first conductive layer extending in a second horizontal direction different from the first horizontal direction, the first conductive layer including a metal, a second conductive layer being in contact with an upper surface of the first conductive layer, the second conductive layer including a metal nitride containing the metal, a third conductive layer being in contact with an upper surface of the second conductive layer, the third conductive layer including the metal, and a first upper interlayer insulating layer disposed on an upper surface of the lower interlayer insulating layer, the first upper interlayer insulating layer being in contact with sidewalls of the first to third conductive layers in the first horizontal direction, wherein the sidewalls of the first to third conductive layers in the first horizontal direction, which are in contact with the first upper interlayer insulating layer, have a continuously sloped profile.

### CROSS-REFERENCE TO RELATED APPLICATIONS

This present application claims priority to and the benefit under 35 U.S.C. § 119(a)-(d) of Korean Patent Application No. 10-2025-0053462, filed on Apr. 24, 2025, in the Korean Intellectual Property Office, the entire disclosure of which is incorporated herein by reference.

### FIELD

The present disclosure relates to a semiconductor device including wiring pattern.

### BACKGROUND

With the advancement of electronic technologies, the down-scaling of semiconductor devices has rapidly progressed in recent years, resulting in increasing demands for higher integration and lower power consumption of semiconductor chips. As the spacing between circuit components such as wiring patterns becomes increasingly narrow, reliability issues may arise between the wiring patterns.

### SUMMARY

An object of the present disclosure is to provide a semiconductor device and a method for fabricating the same that may reduce the complexity of the fabrication process and the resistance of wiring layers.

The aspects of the present disclosure are not limited to those described above, and other aspects not explicitly mentioned may be clearly understood by those skilled in the art from the following description.

According to some embodiments of the present disclosure, there is provided a semiconductor device, comprising a lower interlayer insulating layer, a first contact trench formed in the lower interlayer insulating layer, a first contact disposed in the first contact trench, a first conductive layer disposed on an upper surface of the first contact, a width of the first conductive layer in a first horizontal direction greater than a width of the first contact trench in the first horizontal direction, the first conductive layer extending in a second horizontal direction different from the first horizontal direction, the first conductive layer including a metal, a second conductive layer being in contact with an upper surface of the first conductive layer, the second conductive layer including a metal nitride containing the metal, a third conductive layer being in contact with an upper surface of the second conductive layer, the third conductive layer including the metal, and a first upper interlayer insulating layer disposed on an upper surface of the lower interlayer insulating layer, the first upper interlayer insulating layer being in contact with sidewalls of the first to third conductive layers in the first horizontal direction, wherein the sidewalls of the first to third conductive layers in the first horizontal direction, which are in contact with the first upper interlayer insulating layer, have a continuously sloped profile.

According to some embodiments of the present disclosure, there is provided a semiconductor device, comprising a first contact, a first conductive layer disposed on an upper surface of the first contact, the first conductive layer including a metal, a second conductive layer being in contact with an upper surface of the first conductive layer, the second conductive layer including a metal nitride containing the metal, a third conductive layer being in contact with an upper surface of the second conductive layer, the third conductive layer including the metal, a first upper interlayer insulating layer being in contact with sidewalls of the first to third conductive layers in a first horizontal direction, a second upper interlayer insulating layer disposed on an upper surface of the first upper interlayer insulating layer; and an upper wiring pattern disposed on an upper surface of the third conductive layer, the upper wiring pattern extending in a second horizontal direction different from the first horizontal direction, the upper wiring pattern electrically connected to the third conductive layer, wherein a width of the upper surface of the third conductive layer in the first horizontal direction is smaller than a width of the upper surface of the first conductive layer in the first horizontal direction.

According to some embodiments of the present disclosure, there is provided a semiconductor device, comprising a lower interlayer insulating layer, a contact trench formed in the lower interlayer insulating layer, a contact disposed in the contact trench, a wiring barrier layer being in contact with an upper surface of the contact, a first conductive layer being in contact with an upper surface of the wiring barrier layer, a width of the first conductive layer in a first horizontal direction greater than a width of the contact trench in the first horizontal direction, the first conductive layer extending in a second horizontal direction different from the first horizontal direction, the first conductive layer including ruthenium (Ru), a second conductive layer being in contact with an upper surface of the first conductive layer, the second conductive layer including ruthenium nitride (RuN), the second conductive layer extending in the second horizontal direction, a third conductive layer being in contact with an upper surface of the second conductive layer, the third conductive layer including ruthenium (Ru), the third conductive layer extending in the second horizontal direction, a first upper interlayer insulating layer disposed on an upper surface of the lower interlayer insulating layer, the first upper interlayer insulating layer being in contact with sidewalls of the first to third conductive layers in the first horizontal direction, an upper surface of the first upper interlayer insulating layer formed on the same plane as an upper surface of the third conductive layer, a second upper interlayer insulating layer disposed on the upper surface of the first upper interlayer insulating layer, a via disposed in the second upper interlayer insulating layer, the via being in contact with the upper surface of the third conductive layer, and an upper wiring pattern disposed in the second upper interlayer insulating layer, the upper wiring pattern being in contact with an upper surface of the via, the upper wiring pattern formed integrally with the via, the upper wiring pattern extending in the second horizontal direction, wherein the sidewalls of the first to third conductive layers in the first horizontal direction, which are in contact with the first upper interlayer insulating layer, have a continuously sloped profile, and wherein a width of the upper surface of the third conductive layer in the first horizontal direction is smaller than a width of the upper surface of the first conductive layer in the first horizontal direction.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a layout diagram for explaining a semiconductor device according to some embodiments of the present disclosure;

FIG. 2 is a cross-sectional view taken along line A-A′ of FIG. 1;

FIG. 3 is a cross-sectional view taken along line B-B′ of FIG. 1;

FIGS. 4 to 17 are intermediate stage diagrams for explaining a method for fabricating a semiconductor device according to some embodiments of the present disclosure;

FIGS. 18 and 19 are cross-sectional views for explaining a semiconductor device according to some embodiments of the present disclosure;

FIGS. 20 to 27 are intermediate stage diagrams for explaining a method for fabricating a semiconductor device according to some embodiments of the present disclosure;

FIG. 28 is a layout diagram for explaining a semiconductor device according to some embodiments of the present disclosure;

FIG. 29 is a cross-sectional view taken along line C-C′ of FIG. 28;

FIGS. 30 to 36 are intermediate stage diagrams for explaining a method for fabricating a semiconductor device according to embodiments of the present disclosure;

FIG. 37 is a cross-sectional view for explaining a semiconductor device according to embodiments of the disclosure; and

FIGS. 38 to 41 are intermediate stage diagrams for explaining a method for fabricating a semiconductor device according to embodiments of the present disclosure.

### DETAILED DESCRIPTION

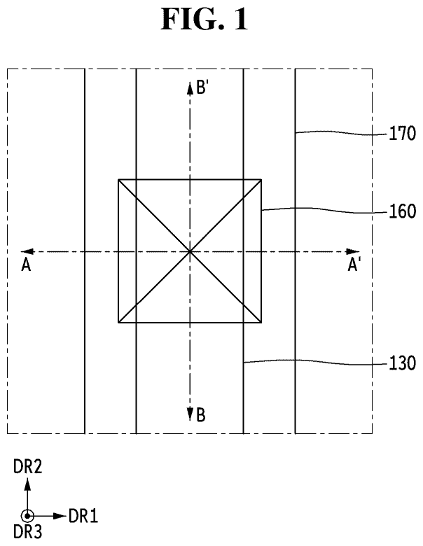

Hereinafter, a semiconductor device according to some embodiments of the present disclosure will be described below with reference to FIGS. 1 to 3.

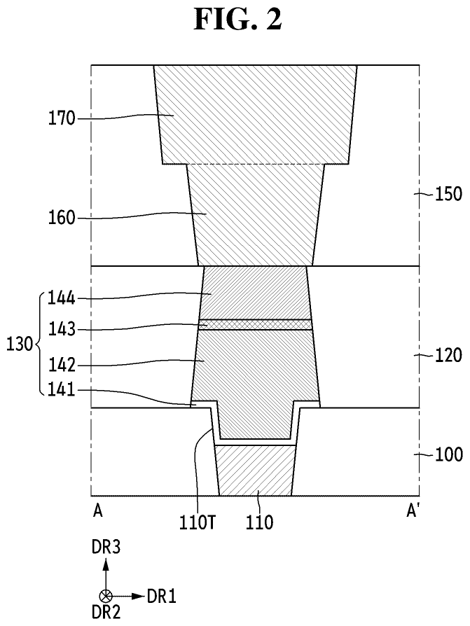

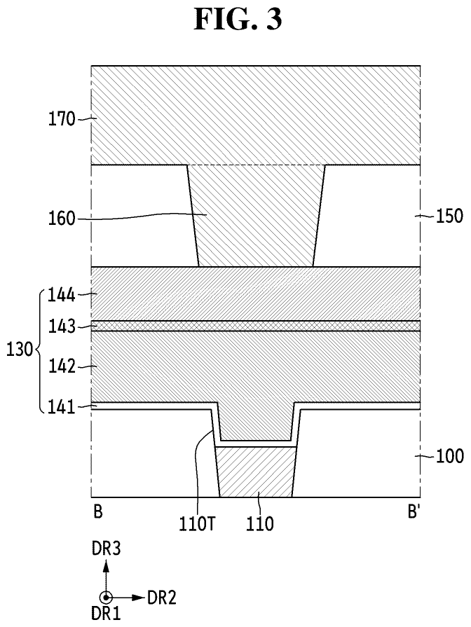

FIG. 1 is a layout diagram for explaining a semiconductor device according to some embodiments of the present disclosure. FIG. 2 is a cross-sectional view taken along line A-A′ of FIG. 1. FIG. 3 is a cross-sectional view taken along line B-B′ of FIG. 1.

Referring to FIGS. 1 to 3, the semiconductor device according to some embodiments of the present disclosure includes a lower interlayer insulating layer 100, a first contact trench 110T, a first contact 110, a first upper interlayer insulating layer 120, a first lower wiring pattern 130, a first wiring barrier layer 141, a first conductive layer 142, a second conductive layer 143, a third conductive layer 144, a second upper interlayer insulating layer 150, a via 160, and an upper wiring pattern 170.

The lower interlayer insulating layer 100 may include, for example, one or more of silicon oxide (SiO₂), silicon nitride (SiN), SiCOH, silicon oxycarbide (SiOC), silicon oxynitride (SiON), and low-k dielectric materials. The low-k dielectric materials may include, for example, Tetraethyl orthosilicate (TEOS), Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylCycloTetraSiloxane (OMCTS), HexaMethylDiSiloxane (HMDS), TriMethylSilyl Borate (TMSB), DiAcetoxyDitertiaryButoxy Siloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica, or combinations thereof. However, the present disclosure is not limited thereto.

Hereinafter, a first horizontal direction DR1 and a second horizontal direction DR2 may each be defined as a direction parallel to an upper surface of the lower interlayer insulating layer 100. The second horizontal direction DR2 may be defined as a direction different from the first horizontal direction DR1. A vertical direction DR3 may be defined as a direction perpendicular to each of the first horizontal direction DR1 and the second horizontal direction DR2. That is, the vertical direction DR3 may be defined as a direction perpendicular to the upper surface of the lower interlayer insulating layer 100.

A first contact trench 110T may be formed in the lower interlayer insulating layer 100. For example, the first contact trench 110T may be formed to recess from the upper surface of the lower interlayer insulating layer 100 toward the lower interlayer insulating layer 100. For example, the width of the first contact trench 110T in the first horizontal direction DR1 may gradually increase toward the upper surface of the lower interlayer insulating layer 100. Additionally, the width of the first contact trench 110T in the second horizontal direction DR2 may gradually increase toward the upper surface of the lower interlayer insulating layer 100.

A first contact 110 may be disposed in the first contact trench 110T. For example, the first contact 110 may fill a portion of the first contact trench 110T. For example, an upper surface of the first contact 110 may be formed to be lower than the upper surface of the lower interlayer insulating layer 100. For example, both sidewalls of the first contact 110 in the first horizontal direction DR1 may be in contact with the lower interlayer insulating layer 100. Additionally, both sidewalls of the first contact 110 in the second horizontal direction DR2 may be in contact with the lower interlayer insulating layer 100. For example, the width of the first contact 110 in the first horizontal direction DR1 may gradually increase toward the upper surface of the lower interlayer insulating layer 100. Further, the width of the first contact 110 in the second horizontal direction DR2 may gradually increase toward the upper surface of the lower interlayer insulating layer 100. The first contact 110 may include a conductive material.

A first upper interlayer insulating layer 120 may be disposed on the upper surface of the lower interlayer insulating layer 100. For example, the first upper interlayer insulating layer 120 may include at least one of silicon oxide (SiO₂), silicon nitride (SiN), SiCOH, silicon oxycarbide (SiOC), silicon oxynitride (SiON), and low-k dielectric materials. For example, the first upper interlayer insulating layer 120 may be in contact with the upper surface of the lower interlayer insulating layer 100. However, the present disclosure is not limited thereto. In some embodiments, an etching stop layer may be disposed between the upper surface of the lower interlayer insulating layer 100 and the first upper interlayer insulating layer 120. For example, the etching stop layer may be aluminum nitride (AlN), aluminum oxide (Al₂O₃), hafnium oxide (HfO), zirconium oxide (ZrO), hafnium nitride (HfN), zirconium nitride (ZrN), yttrium oxide (Y₂O₃), yttrium nitride (YN), silicon oxide (SiO₂), silicon nitride (SiN), silicon carbonitride (SiCN), silicon oxycarbide (SiOC), silicon carbide (SiC), and low-k dielectric materials.

A first lower wiring pattern 130 may be disposed in the first upper interlayer insulating layer 120. The first lower wiring pattern 130 may be disposed on the upper surface of the first contact 110. For example, the first lower wiring pattern 130 may be in contact with the upper surface of the first contact 110. The first lower wiring pattern 130 may be electrically connected to the first contact 110. For example, the first lower wiring pattern 130 may extend in the second horizontal direction DR2. For example, at least a portion of the first lower wiring pattern 130 may be disposed in the first contact trench 110T. For example, the first lower wiring pattern 130 may be in contact with the upper surface of the lower interlayer insulating layer 100 adjacent to the first contact trench 110T. For example, an upper surface of the first lower wiring pattern 130 may be formed on the same plane as an upper surface of the first upper interlayer insulating layer 120.

For example, the width of the first lower wiring pattern 130 in the first horizontal direction DR1 may be greater than the width of the first contact trench 110T in the first horizontal direction DR1. For example, on the upper surface of the lower interlayer insulating layer 100, both sidewalls of the first lower wiring pattern 130 in the first horizontal direction DR1 may be in contact with the first upper interlayer insulating layer 120. For example, on the upper surface of the lower interlayer insulating layer 100, the sidewall of the first lower wiring pattern 130 in the first horizontal direction DR1 may have a continuously sloped profile. That is, the sidewall of the first lower wiring pattern 130 in the first horizontal direction DR1, which is in contact with the first upper interlayer insulating layer 120 may have a continuously sloped profile. For example, the first lower wiring pattern 130 may include a first wiring barrier layer 141, a first conductive layer 142, a second conductive layer 143, and a third conductive layer 144.

For example, the first wiring barrier layer 141 may be disposed on the upper surface of the first contact 110 and on the upper surface of the lower interlayer insulating layer 100. Additionally, the first wiring barrier layer 141 may be disposed along the sidewall of the first contact trench 110T on the upper surface of the first contact 110. For example, the first wiring barrier layer 141 may be in contact with the upper surface of the first contact 110 and the lower interlayer insulating layer 100. For example, the first wiring barrier layer 141 may be formed conformally. For example, on the upper surface of the lower interlayer insulating layer 100, the sidewall of the first wiring barrier layer 141 in the first horizontal direction DR1 may be in contact with the first upper interlayer insulating layer 120.

The first wiring barrier layer 141 may include a conductive material. For example, the first wiring barrier layer 141 may include one or more of titanium (Ti), titanium nitride (TiN), tantalum (Ta), tantalum nitride (TaN), tantalum carbonitride (TaCN), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), or a combination thereof. However, the present disclosure is not limited thereto.

The first conductive layer 142 may be disposed on the upper surface of the first wiring barrier layer 141. The lower surface of the first conductive layer 142 may be in contact with the upper surface of the first wiring barrier layer 141. That is, the first wiring barrier layer 141 may be disposed between the upper surface of the first contact 110 and the lower surface of the first conductive layer 142. For example, the first conductive layer 142 may extend in the second horizontal direction DR2. For example, the width of the first conductive layer 142 in the first horizontal direction DR1 may be greater than the width of the first contact trench 110T in the first horizontal direction DR1. For example, at least a portion of the first conductive layer 142 may be disposed in the first contact trench 110T. For example, both sidewalls of the first conductive layer 142 in the first horizontal direction DR1 may be in contact with the first upper interlayer insulating layer 120.

The first conductive layer 142 may include a metal. For example, the metal included in the first conductive layer 142 may include ruthenium (Ru). In some embodiments, the metal included in the first conductive layer 142 may include any one of copper (Cu), silver (Ag), cobalt (Co), tantalum (Ta), indium (In), tin (Sn), zinc (Zn), manganese (Mn), titanium (Ti), magnesium (Mg), chromium (Cr), strontium (Sr), platinum (Pt), aluminum (Al), zirconium (Zr), tungsten (W), iridium (Ir), or rhodium (Rh).

The second conductive layer 143 may be disposed on the upper surface of the first conductive layer 142. A lower surface of the second conductive layer 143 may be in contact with the upper surface of the first conductive layer 142. For example, the second conductive layer 143 may extend in the second horizontal direction DR2. In FIGS. 2 and 3, the thickness of the second conductive layer 143 in the vertical direction DR3 is shown to be formed uniformly, but the present disclosure is not limited thereto. That is, in some embodiments, the thickness of the second conductive layer 143 in the vertical direction DR3 may be formed unevenly. For example, both sidewalls of the second conductive layer 143 in the first horizontal direction DR1 may be in contact with the first upper interlayer insulating layer 120.

The second conductive layer 143 may include a metal nitride containing the metal included in the first conductive layer 142. For example, if the first conductive layer 142 includes ruthenium (Ru), the second conductive layer 143 may include ruthenium nitride (RuN). In some embodiments, the metal contained in the second conductive layer 143 may include a nitride of any one of copper (Cu), silver (Ag), cobalt (Co), tantalum (Ta), indium (In), tin (Sn), zinc (Zn), manganese (Mn), titanium (Ti), magnesium (Mg), chromium (Cr), strontium (Sr), platinum (Pt), aluminum (Al), zirconium (Zr), tungsten (W), iridium (Ir), or rhodium (Rh).

The third conductive layer 144 may be disposed on an upper surface of the second conductive layer 143. A lower surface of the third conductive layer 144 may be in contact with the upper surface of the second conductive layer 143. For example, the third conductive layer 144 may extend in the second horizontal direction DR2. In FIGS. 2 and 3, the thickness of the third conductive layer 144 in the vertical direction DR3 is shown to be formed uniformly, but the present disclosure is not limited thereto. That is, in some embodiments, the thickness of the third conductive layer 144 in the vertical direction DR3 may be formed unevenly.

For example, both sidewalls of the third conductive layer 144 in the first horizontal direction DR1 may be in contact with the first upper interlayer insulating layer 120. For example, the upper surface of the third conductive layer 144 may be formed on the same plane as the upper surface of the first upper interlayer insulating layer 120. For example, the sidewall of each of the first wiring barrier layer 141, the first conductive layer 142, the second conductive layer 143, and the third conductive layer 144 in the first horizontal direction DR1, which is in contact with the first upper interlayer insulating layer 120, may have a continuously sloped profile. For example, the width of the upper surface of the third conductive layer 144 in the first horizontal direction DR1 may be smaller than the width of the upper surface of the first conductive layer 142 in the first horizontal direction DR1.

The third conductive layer 144 may include the metal contained in the first conductive layer 142. That is, the third conductive layer 144 may include the same metal as the first conductive layer 142. For example, if the first conductive layer 142 includes ruthenium (Ru), the third conductive layer 144 may include ruthenium (Ru). In some embodiments, the metal contained in the third conductive layer 44 may include any one of copper (Cu), silver (Ag), cobalt (Co), tantalum (Ta), indium (In), tin (Sn), zinc (Zn), manganese (Mn), titanium (Ti), magnesium (Mg), chromium (Cr), strontium (Sr), platinum (Pt), aluminum (Al), zirconium (Zr), tungsten (W), iridium (Ir), or rhodium (Rh).

In some embodiments, the first wiring barrier layer 141 may not be provided. In this case, the lower surface of the first conductive layer 142 may be in contact with the upper surface of the first contact 110 and the lower interlayer insulating layer 100.

In some embodiments, at least one of the first conductive layer 142 and the third conductive layer 144 may also include nitrogen atoms. For example, if the first conductive layer 142 includes nitrogen atoms, the concentration of nitrogen atoms contained in the first conductive layer 142 may increase toward the upper surface of the first conductive layer 142 from the lower surface of the first conductive layer 142. For example, if the third conductive layer 144 includes nitrogen atoms, the concentration of nitrogen atoms contained in the third conductive layer 144 may increase toward the lower surface of the third conductive layer 144 from the upper surface of the third conductive layer 144. For example, if both the first conductive layer 142 and the third conductive layer 144 include nitrogen atoms, the concentration of nitrogen atoms contained in the third conductive layer 144 may be greater than the concentration of nitrogen atoms contained in the first conductive layer 142.

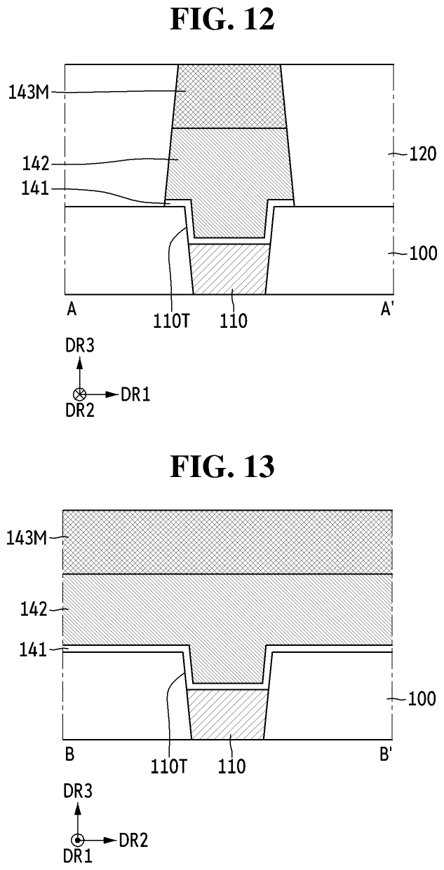

In some embodiments, the second conductive layer 143 may not be provided. That is, the third conductive layer 144 may be in contact with the upper surface of the first conductive layer 142. For example, in the fabrication process described later, the entire second conductive material layer 143M (see FIGS. 12 and 13) may be replaced with the third conductive layer 144, so that the second conductive layer 143 may not be disposed. For example, even if the second conductive layer 143 is not disposed, at least one of the first conductive layer 142 and the third conductive layer 144 may include nitrogen atoms. For example, if the first conductive layer 142 includes nitrogen atoms, the concentration of nitrogen atoms included in the first conductive layer 142 may increase from the lower surface of the first conductive layer 142 toward the upper surface of the first conductive layer 142 that is in contact with the lower surface of the third conductive layer 144. For example, if the third conductive layer 144 includes nitrogen atoms, the concentration of nitrogen atoms included in the third conductive layer 144 may increase from the upper surface of the third conductive layer 144 toward the lower surface of the third conductive layer 144 that is in contact with the upper surface of the first conductive layer 142. For example, when each of the first conductive layer 142 and the third conductive layer 144 contains nitrogen atoms, the concentration of nitrogen atoms included in the third conductive layer 144 may be greater than the concentration of nitrogen atoms included in the first conductive layer 142.

The second upper interlayer insulating layer 150 may be disposed on the upper surface of the first upper interlayer insulating layer 120. A lower surface of the second upper interlayer insulating layer 150 may be in contact with the upper surface of the first upper interlayer insulating layer 120. For example, the second upper interlayer insulating layer 150 may include the same material as the first upper interlayer insulating layer 120. However, the present disclosure is not limited thereto. In some embodiments, the second upper interlayer insulating layer 150 may include a material different from that of the first upper interlayer insulating layer 120. For example, the second upper interlayer insulating layer 150 may include one or more of silicon oxide (SiO₂), silicon nitride (SiN), SiCOH, silicon carbide (SiOC), silicon oxynitride (SiON), and low-k dielectric materials.

The via 160 may be disposed in the second upper interlayer insulating layer 150. The via 160 may be disposed on the upper surface of the first lower wiring pattern 130. For example, the via 160 may be in contact with the upper surface of the first lower wiring pattern 130. That is, the via 160 may be in contact with the upper surface of the third conductive layer 144. The via 160 may be electrically connected to the first lower wiring pattern 130. Sidewalls of the via 160 may be surrounded by the second upper interlayer insulating layer 150. For example, both sidewalls of the via 160 in the first horizontal direction DR1 may be in contact with the second upper interlayer insulating layer 150. In addition, both sidewalls of the via 160 in the second horizontal direction DR2 may also be in contact with the second upper interlayer insulating layer 150.

For example, the width of the via 160 in the first horizontal direction DR1 may gradually increase toward the upper surface of the second upper interlayer insulating layer 150. Likewise, the width of the via 160 in the second horizontal direction DR2 may also gradually increase toward the upper surface of the second upper interlayer insulating layer 150. In FIG. 2, the width of the lower surface of the via 160 in the first horizontal direction DR1 is shown to be greater than the width of the upper surface of the third conductive layer 144 in the first horizontal direction DR1, but the present disclosure is not limited thereto. In some embodiments, the width of the lower surface of the via 160 in the first horizontal direction DR1 may be smaller than the width of the upper surface of the third conductive layer in the first horizontal direction DR1. The via 160 may include a conductive material.

An upper wiring pattern 170 may be disposed in the second upper interlayer insulating layer 150. The upper wiring pattern 170 may be disposed on an upper surface of the via 160. For example, the upper wiring pattern 170 may be in contact with the upper surface of the via 160. The upper wiring pattern 170 may be electrically connected to the via 160. That is, the upper wiring pattern 170 may be electrically connected to the first lower wiring pattern 130 through the via 160. For example, the upper wiring pattern 170 may extend in the second horizontal direction DR2. Both sidewalls of the upper wiring pattern 170 in the first horizontal direction DR1 may be in contact with the second upper interlayer insulating layer 150.

For example, the upper surface of the upper wiring pattern 170 may be formed on the same plane as the upper surface of the second upper interlayer insulating layer 150. For example, the width of the lower surface of the upper wiring pattern 170 in the second horizontal direction DR2 may be greater than the width of the upper surface of the via 160 in the second horizontal direction DR2. Similarly, the width of the lower surface of the upper wiring pattern 170 in the first horizontal direction DR1 may be greater than the width of the upper surface of the via 160 in the first horizontal direction DR1. However, the present disclosure is not limited thereto. In some embodiments, the width of the lower surface of the upper wiring pattern 170 in the first horizontal direction DR1 may be the same as the width of the upper surface of the via 160 in the first horizontal direction DR1. That is, the sidewalls of the upper wiring pattern 170 in the first horizontal direction DR1 may form a continuously sloped profile with the sidewalls of the via 160 in the first horizontal direction DR1.

For example, the width of the upper wiring pattern 170 in the first horizontal direction DR1 may gradually increase toward the upper surface of the second upper interlayer insulating layer 150. Additionally, the width of the upper wiring pattern 170 in the second horizontal direction DR2 may gradually increase toward the upper surface of the second upper interlayer insulating layer 150. For example, the upper wiring pattern 170 may be integrally formed with the via 160. That is, the upper wiring pattern 170 and the via 160 may be formed through the same fabrication process. Additionally, the upper wiring pattern 170 and the via 160 may include the same conductive material.

Hereinafter, a method for fabricating a semiconductor device according to some embodiments of the present disclosure will be described with reference to FIGS. 2 to 17.

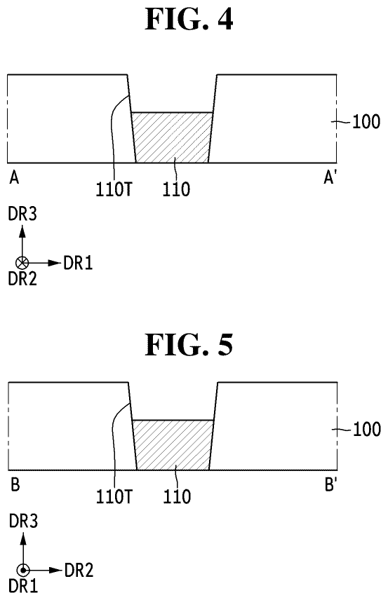

FIGS. 4 to 17 are intermediate stage diagrams for explaining a method for fabricating a semiconductor device according to some embodiments of the present disclosure.

Referring to FIGS. 4 and 5, a first contact trench 110T may be formed in the lower interlayer insulating layer 100. Subsequently, a first contact 110 may be formed in the first contact trench 110T. For example, the upper surface of the first contact 110 may formed to be lower than the upper surface of the lower interlayer insulating layer 100.

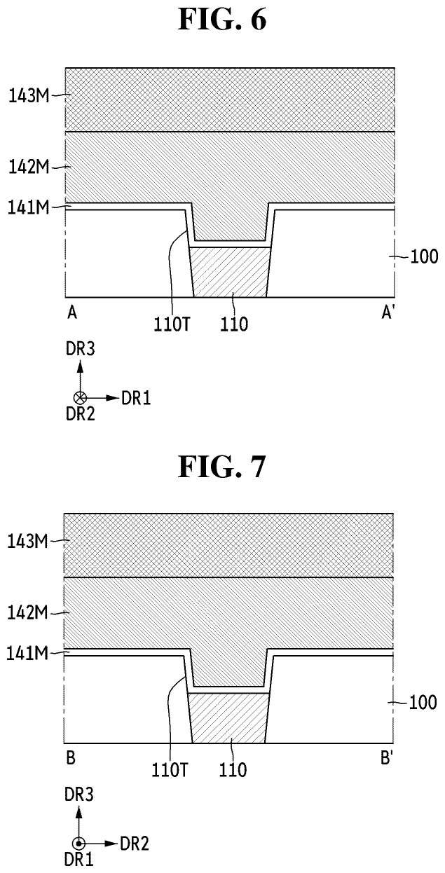

Referring to FIGS. 6 and 7, a wiring barrier material layer 141M may be formed on the upper surface of the first contact 110 and on the upper surface of the lower interlayer insulating layer 100. Additionally, the wiring barrier material layer 141M may be formed along sidewalls of the first contact trench 110T on the upper surface of the first contact 110. For example, the wiring barrier material layer 141M may be in contact with the upper surface of the first contact 110 and the lower interlayer insulating layer 100. The wiring barrier material layer 141M may be formed conformally. For example, the wiring barrier material layer 141M may include the same material as the first wiring barrier layer 141 shown in FIGS. 2 and 3.

Subsequently, a first conductive material layer 142M may be formed on the upper surface of the wiring barrier material layer 141M. For example, the first conductive material layer 142M may be in contact with the upper surface of the wiring barrier material layer 141M. For example, at least a portion of the first conductive material layer 142M may be formed in the first contact trench 110T. For example, the first conductive material layer 142M may include the same material as the first conductive layer 142 shown in FIGS. 2 and 3. That is, the first conductive material layer 142M may include a metal.

Next, a second conductive material layer 143M may be formed on the upper surface of the first conductive material layer 142M. For example, the second conductive material layer 143M may be in contact with the upper surface of the first conductive material layer 142M. For example, the second conductive material layer 143M may include the same material as the second conductive layer 143 shown in FIGS. 2 and 3. That is, the second conductive material layer 143M may include a metal nitride that contains the metal included in the first conductive material layer 142M.

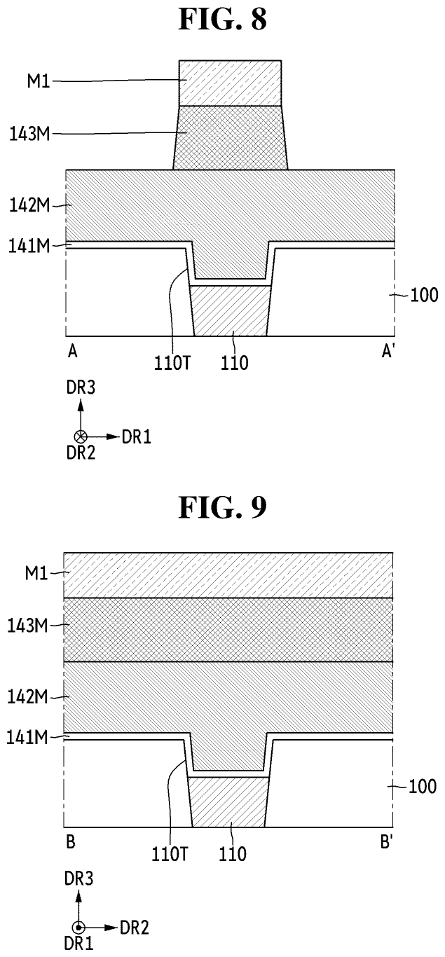

Referring to FIGS. 8 and 9, a first mask pattern M1 may be formed on the upper surface of the second conductive material layer 143M. For example, the first mask pattern M1 may overlap the first contact 110 in the vertical direction DR3. For example, the first mask pattern M1 may extend in the second horizontal direction DR2. Thereafter, using the first mask pattern M1 as a mask, a portion of the second conductive material layer 143M may be etched.

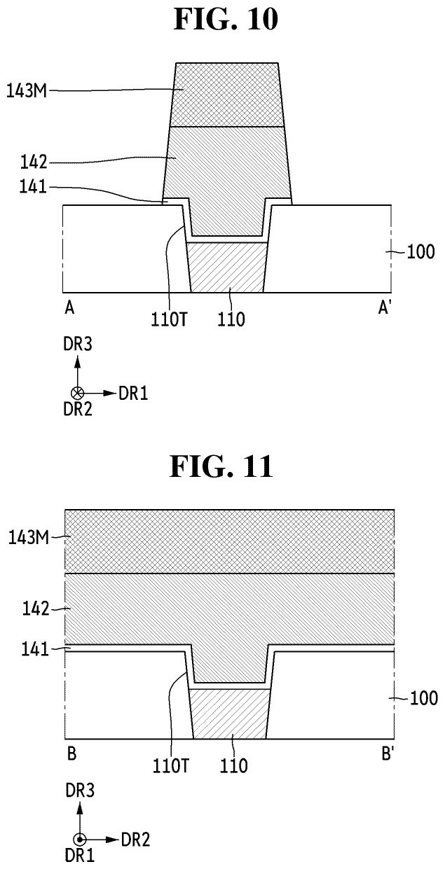

Referring to FIGS. 10 and 11, the first mask pattern M1 (see FIGS. 8 and 9) may be removed. Then, using the remaining second conductive material layer 143M as a mask, a portion of the first conductive material layer 142M (see FIGS. 8 and 9) and a portion of the wiring barrier material layer 141M (see FIGS. 8 and 9) may be etched. After the etching process is completed, the remaining first conductive material layer 142M (see FIGS. 8 and 9) may be defined as the first conductive layer 142, and the remaining wiring barrier material layer 141M (see FIGS. 8 and 9) may be defined as the first wiring barrier layer 141.

For example, the sidewalls of the remaining second conductive material layer 143M, the first conductive layer 142, and the first wiring barrier layer 141 in the first horizontal direction DR1 may each have a continuously sloped profile. For example, the remaining second conductive material layer 143M and the first conductive layer 142 may each extend in a second horizontal direction DR2.

Referring to FIGS. 12 and 13, the first upper interlayer insulating layer 120 may be formed to cover the second conductive material layer 143M, the first conductive layer 142, and the first wiring barrier layer 141 on the upper surface of the lower interlayer insulating layer 100, respectively. Subsequently, a planarization process may be performed to expose the upper surface of the second conductive material layer 143M. As a result, the upper surface of the second conductive material layer 143M and the upper surface of the first upper interlayer insulating layer 120 may be formed on the same plane. For example, the first upper interlayer insulating layer 120 may be in contact with both sidewalls of the second conductive material layer 143M, the first conductive layer 142, and the first wiring barrier layer 141 in the first horizontal direction DR1, respectively.

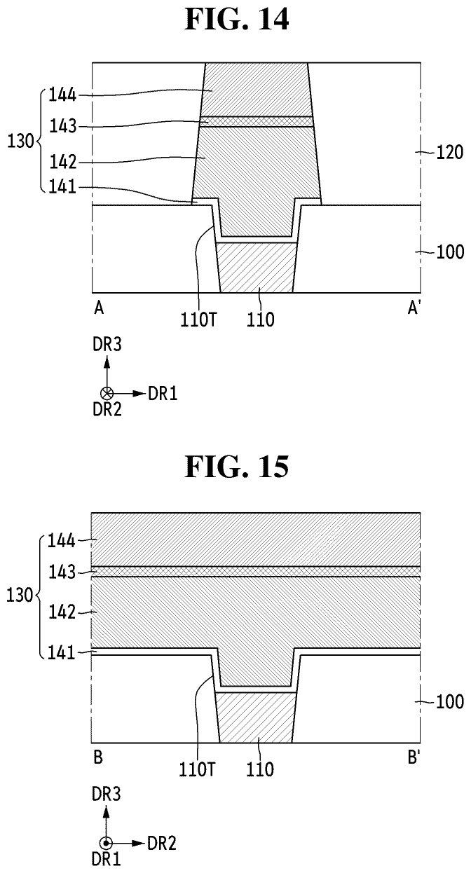

Referring to FIGS. 14 and 15, an annealing process may be performed to remove nitrogen from a portion of the second conductive material layer 143M (see FIGS. 12 and 13). For example, a portion of the second conductive material layer 143M (see FIGS. 12 and 13) from which nitrogen has been removed from the second conductive material layer 143M (see FIGS. 12 and 13) may be defined as the third conductive layer 144. Additionally, the remaining portion of the second conductive material layer 143M (see FIG. 12 and FIG. 13) from which nitrogen is not removed from the second conductive material layer 143M (see FIG. 12 and FIG. 13) may be defined as the second conductive layer 143.

For example, the second conductive layer 143 may be formed so as to be in contact with the upper surface of the first conductive layer 142. The third conductive layer 144 may be formed on the upper surface of the second conductive layer 143. For example, the upper surface of the third conductive layer 144 may be formed on the same plane as the upper surface of the first upper interlayer insulating layer 120. For example, the first conductive layer 142, the second conductive layer 143, and the third conductive layer 144 may each extend in the second horizontal direction DR2. For example, the sidewalls of the first wiring barrier layer 141, the first conductive layer 142, the second conductive layer 143, and the third conductive layer 144 in the first horizontal direction DR1 may be in contact with the first upper interlayer insulating layer 120. For example, the sidewalls of the first wiring barrier layer 141, the first conductive layer 142, the second conductive layer 143, and the third conductive layer 144 in the first horizontal direction DR1, which are in contact with the first upper interlayer insulating layer 120, may have a continuously sloped profile.

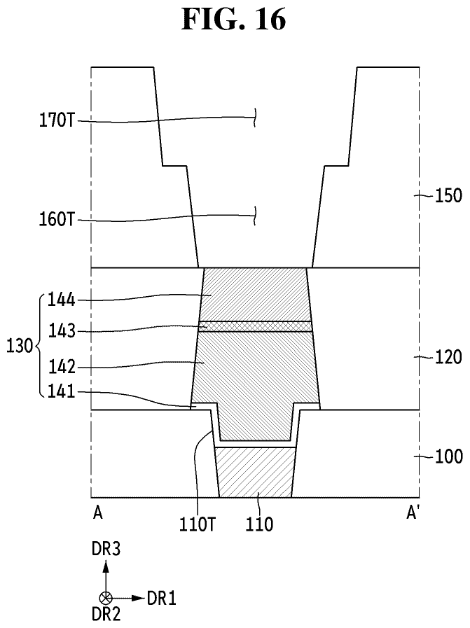

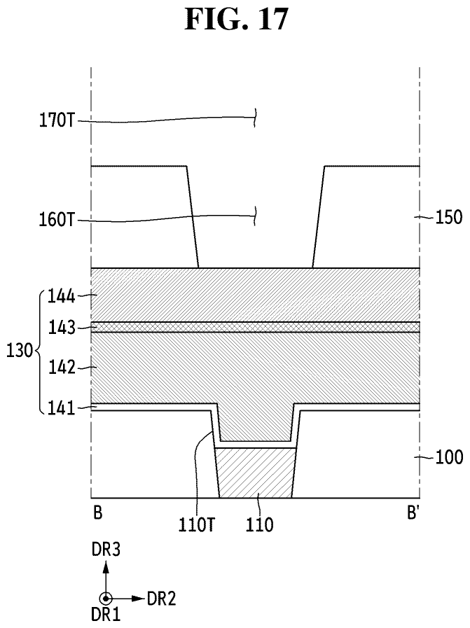

Referring to FIGS. 16 and 17, the second upper interlayer insulating layer 150 may be formed on the upper surfaces of the first upper interlayer insulating layer 120 and the third conductive layer 144. Subsequently, a via trench 160T and an upper wiring trench 170T may be formed in the second upper interlayer insulating layer 150. For example, the via trench 160T may be formed on the upper surface of the third conductive layer 144. The upper surface of the third conductive layer 144 may be exposed through a bottom surface of the via trench 160T.

The upper wiring trench 170T may be formed above the via trench 160T. For example, a width of the upper wiring trench 170T in the first horizontal direction DR1 may be greater than a width of the via trench 160T in the first horizontal direction DR1. For example, the upper wiring trench 170T may extend in the second horizontal direction DR2. For example, the via trench 160T and the upper wiring trench 170T may be formed through the same fabrication process. However, the present disclosure is not limited thereto.

Referring to FIGS. 2 and 3, the via 160 may be formed in the via trench 160T (see FIGS. 16 and 17), and the upper wiring pattern 170 may be formed in the upper wiring trench 170T (see FIGS. 16 and 17). For example, the via 160 may be in contact with the upper surface of the third conductive layer 144. The upper wiring pattern 170 may be in contact with the upper surface of the via 160. For example, the via 160 and the upper wiring pattern 170 may be formed integrally. Through such a fabrication process, the semiconductor device shown in FIGS. 2 and 3 may be fabricated.

In a method for fabricating a semiconductor device according to some embodiments of the present disclosure, after the second conductive material layer 143M is etched using the first mask pattern M1 as a mask, the first conductive material layer 142M may be etched using the remaining second conductive material layer 143M as a mask to form the first conductive layer 142. That is, by etching only the second conductive material layer 143M using the first mask pattern M1 as a mask, rather than etching both the first and second conductive material layers 142M, 143M using the first mask pattern M1 as a mask, the thickness of the first mask pattern M1 in the vertical direction DR3 may be relatively reduced. Accordingly, the method for fabricating a semiconductor device according to some embodiments of the present disclosure may reduce the aspect ratio of the first mask pattern M1, thereby lowering the process complexity.

Furthermore, in some embodiments of the present disclosure, the method for fabricating a semiconductor device may include replacing a portion of the second conductive material layer 143M with a third conductive layer 144 containing a metal by removing nitrogen from the second conductive material layer 143M used as a mask for etching the first conductive material layer 142M. As a result, the method for fabricating a semiconductor device according to some embodiments of the present disclosure may reduce the resistance of the third conductive layer 144 and thereby improve the electrical characteristics of the semiconductor device.

The semiconductor device according to some embodiments of the present disclosure, fabricated by the fabrication method described above, may have a first conductive layer 142, a second conductive layer 143, and a third conductive layer 144 sequentially stacked, wherein the first conductive layer 142 and the third conductive layer 144 may include the same metal, and the second conductive layer 143 may include a metal nitride containing the metal. Additionally, the sidewalls of each of the first conductive layer 142, the second conductive layer 143, and the third conductive layer 144 in the first horizontal direction DR1 may be in contact with the first upper interlayer insulating layer 120. The sidewalls of each of the first conductive layer 142, the second conductive layer 143, and the third conductive layer 144 in the first horizontal direction DR1, which are in contact with the first upper interlayer insulating layer 120, may have a continuously sloped profile.

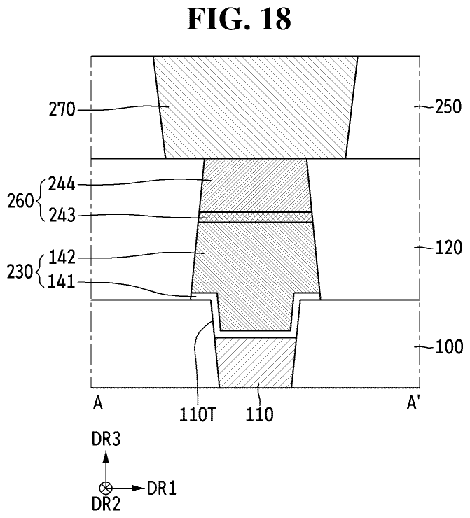

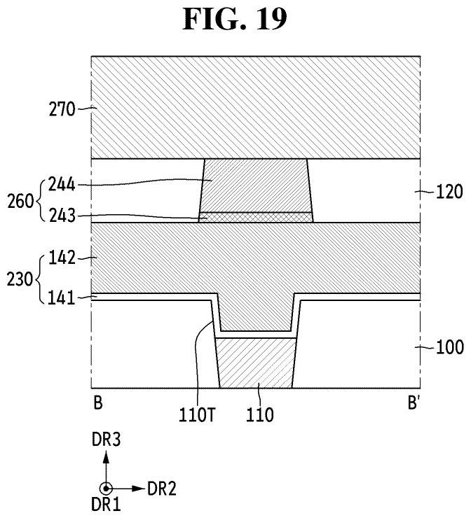

Hereinafter, with reference to FIGS. 18 and 19, a semiconductor device according to embodiments of the present disclosure will be described, focusing on differences from the semiconductor device shown in FIGS. 1 to 3.

FIGS. 18 and 19 are cross-sectional views for explaining a semiconductor device according to several embodiments of the present disclosure.

Referring to FIGS. 18 and 19, a semiconductor device according to embodiments of the present disclosure may have an upper wiring pattern 270 that is in contact with the upper surface of the third conductive layer 244.

For example, a second upper interlayer insulating layer 250 may be disposed on the upper surface of the first upper interlayer insulating layer 120. The upper wiring pattern 270 may be disposed in the second upper interlayer insulating layer 250. The upper wiring pattern 270 may extend in the second horizontal direction DR2. For example, the upper wiring pattern 270 may be electrically connected to a first lower wiring pattern 230 through a via 260. For example, the first lower wiring pattern 230 may include the first wiring barrier layer 141 and the first conductive layer 142. The first lower wiring pattern 230 may extend in the second horizontal direction DR2. That is, each of the first wiring barrier layer 141 and the first conductive layer 142 may extend in the second horizontal direction DR2. For example, the via 260 may include a second conductive layer 243 and a third conductive layer 244.

For example, the sidewalls of the first wiring barrier layer 141, the first conductive layer 142, the second conductive layer 243, and the third conductive layer 244 in the first horizontal direction DR1, each of which is in contact with the first upper interlayer insulating layer 120, may have a continuously sloped profile. For example, sidewalls of the second conductive layer 243 and the third conductive layer 244 in the second horizontal direction DR2 may be in contact with the first upper interlayer insulating layer 120. For example, the upper surface of the first conductive layer 142 may be in contact with the first upper interlayer insulating layer 120 on the sidewalls of the second conductive layer 243 and the third conductive layer 244 in the second horizontal direction DR2.

In some embodiments, the first wiring barrier layer 141 may not be provided. That is, the lower surface of the first conductive layer 142 may be in contact with the upper surface of the first contact 110 and the lower interlayer insulating layer 100. In some embodiments, at least one of the first conductive layer 142 and the third conductive layer 244 may include nitrogen atoms. In some embodiments, the second conductive layer 243 may not be provided. That is, the third conductive layer 244 may be in contact with the upper surface of the first conductive layer 142. For example, even if the second conductive layer 243 is not provided, at least one of the first conductive layer 142 and the third conductive layer 244 may include nitrogen atoms. The description of the distribution and the relative difference in the concentration of nitrogen atoms in the first conductive layer 142 and the third conductive layer 244 are the same as those described with reference to FIGS. 1 to 3, and thus, a detailed explanation thereof will be omitted.

Hereinafter, a method for fabricating a semiconductor device according to several embodiments of the present disclosure will be described with reference to FIGS. 18 to 27. The description will focus on differences from the method for fabricating the semiconductor device shown in FIGS. 4 to 17.

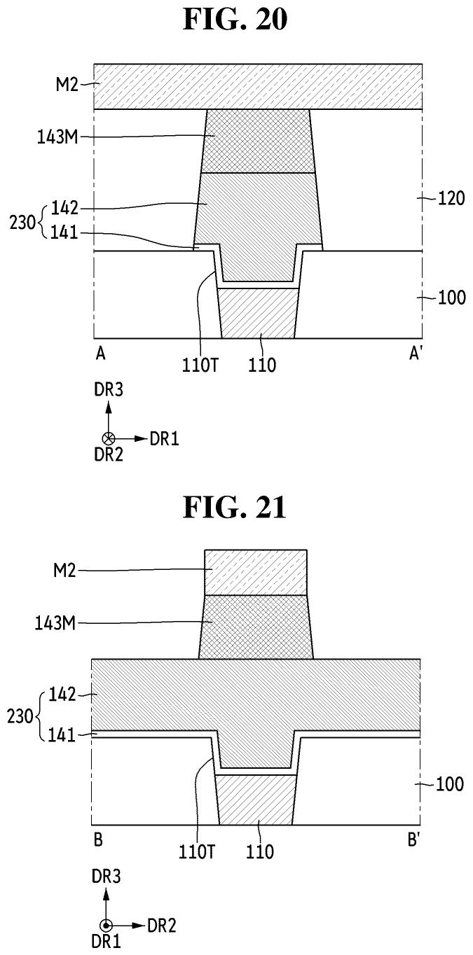

FIGS. 20 to 27 are intermediate stage diagrams for explaining a method for fabricating a semiconductor device according to several embodiments of the present disclosure.

Referring to FIGS. 20 and 21, after performing the fabrication process shown in FIGS. 4 to 13, a second mask pattern M2 may be formed on the upper surface of the remaining second conductive material layer 143M and on the upper surface of the first upper interlayer insulating layer 120. The second mask pattern M2 may overlap the first contact 110 in the vertical direction DR3. For example, in FIG. 21, which is a cross-sectional view taken along the second horizontal direction DR2, the second mask pattern M2 may be formed on a portion of the upper surface of the remaining second conductive material layer 143M.

Subsequently, using the second mask pattern M2 as a mask, a portion of the second conductive material layer 143M may be etched. Through this etching process, both sidewalls of the second conductive material layer 143M in the second horizontal direction DR2 may be exposed. After the etching process is completed, the remaining first wiring barrier layer 141 and the first conductive layer 142 may be defined as the first lower wiring pattern 230.

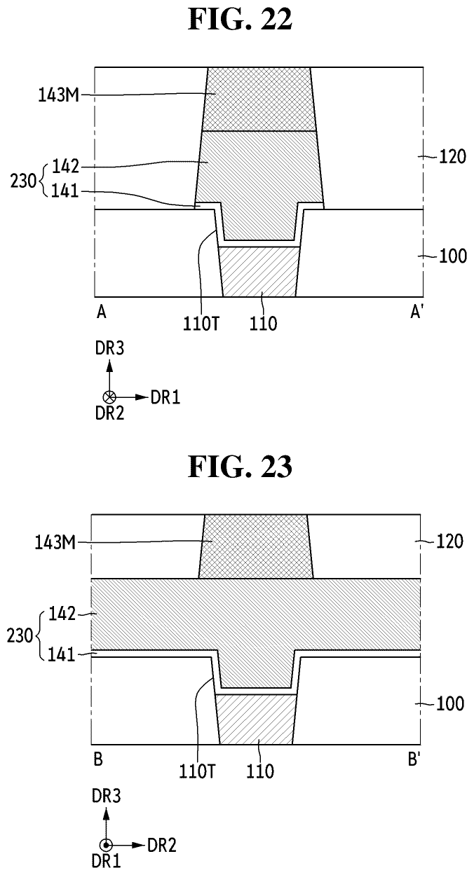

Referring to FIGS. 22 and 23, the second mask pattern M2 (see FIGS. 20 and 21) may be removed. Then, the first upper interlayer insulating layer 120 may be additionally formed to cover both sidewalls and the upper surface of the second conductive material layer 143M in the second horizontal direction DR2. Thereafter, a planarization process may be performed so that the upper surface of the second conductive material layer 143M may be exposed. The upper surface of the second conductive material layer 143M and the upper surface of the first upper interlayer insulating layer 120 may be formed on the same plane.

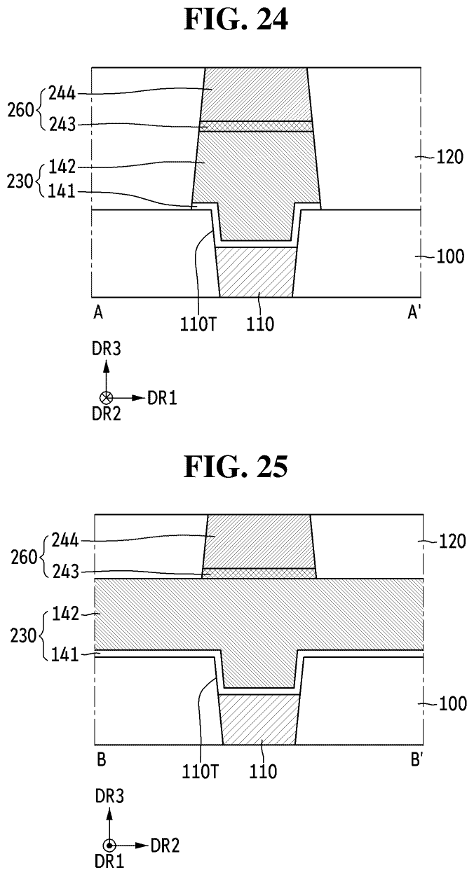

Referring to FIGS. 24 and 25, an annealing process may be performed to remove nitrogen from a portion of the second conductive material layer 143M (see FIGS. 22 and 23). For example, the portion of the second conductive material layer 143M (see FIGS. 22 and 23) from which nitrogen is removed may be defined as a third conductive layer 244. Additionally, the remaining portion of the second conductive material layer 143M (see FIGS. 22 and 23) from which nitrogen has not been removed from the second conductive material layer 143M (see FIGS. 22 and 23) may be defined as a second conductive layer 243. For example, the second conductive layer 243 and the third conductive layer 244 may be defined as a via 260.

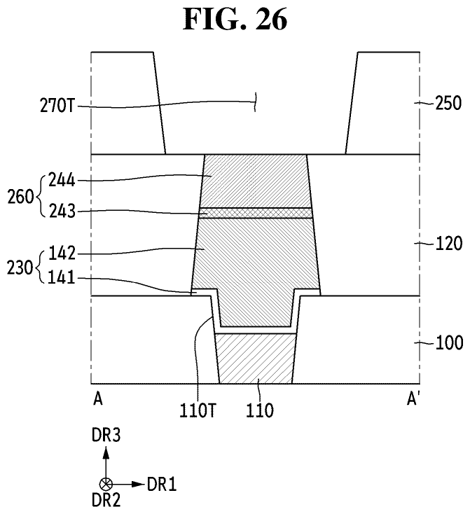

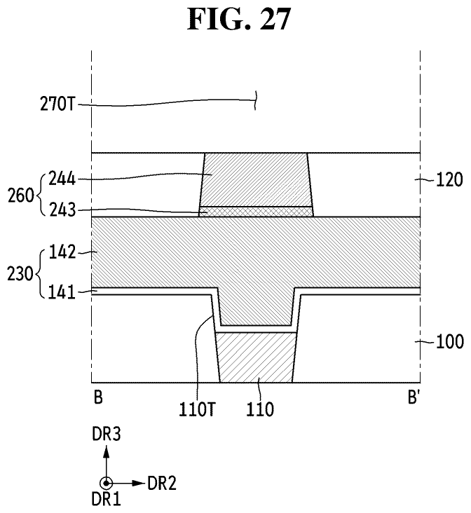

Referring to FIGS. 26 and 27, a second upper interlayer insulating layer 250 may be formed on the upper surface of the first upper interlayer insulating layer 120 and the upper surface of the third conductive layer 244. Then, an upper wiring trench 270T may be formed in the second upper interlayer insulating layer 250. For example, the upper wiring trench 270T may be formed on the upper surface of the third conductive layer 244. Through the bottom surface of the upper wiring trench 270T, the upper surface of the third conductive layer 244 may be exposed. For example, the upper wiring trench 270T may extend in the second horizontal direction DR2.

Referring to FIGS. 18 and 19, an upper wiring pattern 270 may be formed in the upper wiring trench 270T (see FIGS. 26 and 27). For example, the upper wiring pattern 270 may be in contact with the upper surface of the third conductive layer 244. Through the above-described fabrication process, the semiconductor device shown in FIGS. 18 and 19 may be fabricated.

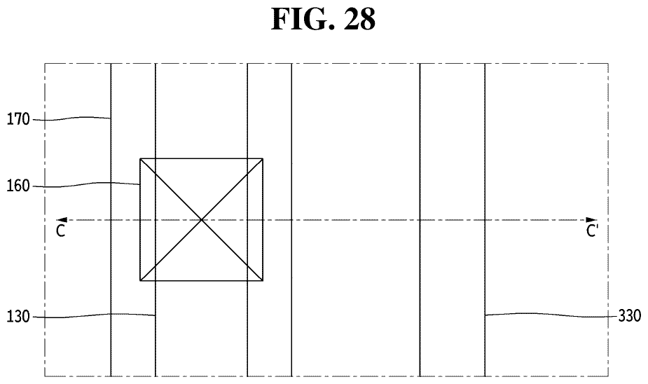

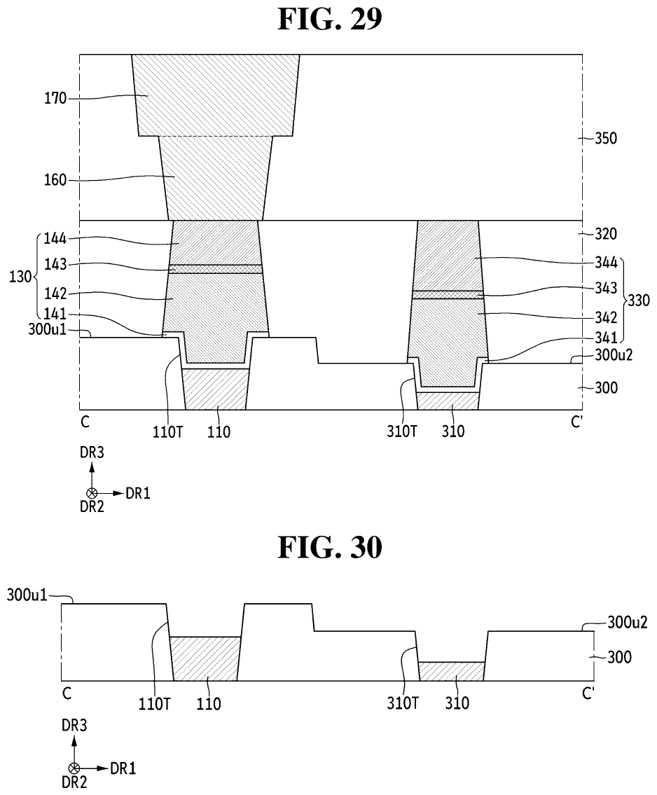

Hereinafter, with reference to FIGS. 28 and 29, a semiconductor device according to embodiments of the present disclosure will be described. The description will focus on differences from the semiconductor device shown in FIGS. 1 to 3.

FIG. 28 is a layout diagram for explaining a semiconductor device according to embodiments of the present disclosure. FIG. 29 is a cross-sectional view taken along line C-C′ of FIG. 28.

Referring to FIGS. 28 and 29, a semiconductor device according to embodiments of the present disclosure may include a second contact trench 310T, a second contact 310, and a second lower wiring pattern 330.

For example, the second contact trench 310T may be formed in a lower interlayer insulating layer 300. The second contact trench 310T may be spaced apart from the first contact trench 110T in the first horizontal direction DR1. For example, the second contact trench 310T may be recessed from an upper surface of the lower interlayer insulating layer 300 into the lower interlayer insulating layer 300. For example, the width of the second contact trench 310T in the first horizontal direction DR1 may gradually increase toward the upper surface of the lower interlayer insulating layer 300. For example, the upper surface of the lower interlayer insulating layer 300 may include a first upper surface 300u1 adjacent to the first contact trench 110T and a second upper surface 300u2 adjacent to the second contact trench 310T. For example, the second upper surface 300u2 of the lower interlayer insulating layer 300 may be disposed below the first upper surface 300u1 of the lower interlayer insulating layer 300.

For example, the second contact 310 may be disposed in the second contact trench 310T. For example, the second contact 310 may fill a portion of the second contact trench 310T. For example, the upper surface of the second contact 310 may be formed to be lower than the second upper surface 300u2 of the lower interlayer insulating layer 300. For example, both sidewalls of the second contact 310 in the first horizontal direction DR1 may be in contact with the lower interlayer insulating layer 300. For example, the width of the second contact 310 in the first horizontal direction DR1 may gradually increase toward the second upper surface 300u2 of the lower interlayer insulating layer 300. The second contact 310 may include a conductive material.

For example, the second lower wiring pattern 330 may be disposed in a first upper interlayer insulating layer 320. The second lower wiring pattern 330 may be disposed on the upper surface of the second contact 310. For example, the second lower wiring pattern 330 may be in contact with the upper surface of the second contact 310. The second lower wiring pattern 330 may be electrically connected to the second contact 310. For example, the second lower wiring pattern 330 may be spaced apart from the first lower wiring pattern 130 in the first horizontal direction DR1. For example, the second lower wiring pattern 330 may extend in the second horizontal direction DR2. For example, at least a portion of the second lower wiring pattern 330 may be disposed in the second contact trench 310T. For example, the second lower wiring pattern 330 may be in contact with the second upper surface 300u2 of the lower interlayer insulating layer 300, which is adjacent to the second contact trench 310T. For example, the upper surface of the second lower wiring pattern 330 may be formed on the same plane as the upper surface of the first upper interlayer insulating layer 320.

For example, the width of the second lower wiring pattern 330 in the first horizontal direction DR1 may be greater than the width of the second contact trench 310T in the first horizontal direction DR1. For example, the width of the second lower wiring pattern 330 in the first horizontal direction DR1 may be smaller than the width of the first lower wiring pattern 130 in the first horizontal direction DR1. For example, on the second upper surface 300u2 of the lower interlayer insulating layer 300, both sidewalls of the second lower wiring pattern 330 in the first horizontal direction DR1 may be in contact with the first upper interlayer insulating layer 320. For example, on the second upper surface 300u2 of the lower interlayer insulating layer 300, the sidewalls of the second lower wiring pattern 330 in the first horizontal direction DR1 may have a continuously sloped profile. That is, the sidewalls of the second lower wiring pattern 330 in the first horizontal direction DR1, which are in contact with the first upper interlayer insulating layer 320, may have a continuously sloped profile. For example, the second lower wiring pattern 330 may include a second wiring barrier layer 341, a fourth conductive layer 342, a fifth conductive layer 343, and a sixth conductive layer 344.

For example, the second wiring barrier layer 341 may be disposed on the upper surface of the second contact 310 and on the second upper surface 300u2 of the lower interlayer insulating layer 300. In addition, the second wiring barrier layer 341 may also be formed along the sidewalls of the second contact trench 310T on the upper surface of the second contact 310. For example, the second wiring barrier layer 341 may be in contact with the upper surface of the second contact 310 and the lower interlayer insulating layer 300. For example, the second wiring barrier layer 341 may be formed conformally. For instance, the sidewalls of the second wiring barrier layer 341 in the first horizontal direction DR1 on the second upper surface 300u2 of the lower interlayer insulating layer 300 may be in contact with the first upper interlayer insulating layer 120. The second wiring barrier layer 341 may include the same material as the first wiring barrier layer 141.

For example, the fourth conductive layer 342 may be disposed on the upper surface of the second wiring barrier layer 341. A lower surface of the fourth conductive layer 342 may be in contact with the upper surface of the second wiring barrier layer 341. That is, the second wiring barrier layer 341 may be disposed between the upper surface of the second contact 310 and the lower surface of the fourth conductive layer 342. The fourth conductive layer 342 may be spaced apart from the first conductive layer 142 in the first horizontal direction DR1. For example, the fourth conductive layer 342 may extend in the second horizontal direction DR2. An upper surface of the fourth conductive layer 342 may be formed to be lower than the upper surface of the first conductive layer 142.

For example, the width of the fourth conductive layer 342 in the first horizontal direction DR1 may be greater than the width of the second contact trench 310T in the first horizontal direction DR1. At least a portion of the fourth conductive layer 342 may be formed in the second contact trench 310T. For example, both sidewalls of the fourth conductive layer 342 in the first horizontal direction DR1 may be in contact with the first upper interlayer insulating layer 320. The fourth conductive layer 342 may include the same material as the first conductive layer 142. That is, the fourth conductive layer 342 may include the same metal as the metal included in the first conductive layer 142.

For example, the fifth conductive layer 343 may be disposed on the upper surface of the fourth conductive layer 342. A lower surface of the fifth conductive layer 343 may be in contact with the upper surface of the fourth conductive layer 342. The fifth conductive layer 343 may extend in the second horizontal direction DR2. In FIG. 29, the thickness of the fifth conductive layer 343 in the vertical direction DR3 is shown to be formed uniformly, but the present disclosure is not limited there to. That is, in some embodiments, the thickness of the fifth conductive layer 343 in the vertical direction DR3 may be formed unevenly. For example, both sidewalls of the fifth conductive layer 343 in the first horizontal direction DR1 may be in contact with the first upper interlayer insulating layer 320. The fifth conductive layer 343 may include a metal nitride including the metal contained in the fourth conductive layer 342. For instance, the fifth conductive layer 343 may include a metal nitride including the metal contained in the fourth conductive layer 342.

For example, the sixth conductive layer 344 may be disposed on an upper surface of the fifth conductive layer 343. A lower surface of the sixth conductive layer 344 may be in contact with the upper surface of the fifth conductive layer 343. For example, the sixth conductive layer 344 may extend in the second horizontal direction DR2. In FIG. 29, the thickness of the sixth conductive layer 344 in the vertical direction DR3 is shown to be formed uniformly. However, the present disclosure is not limited thereto. In some embodiments, the thickness of the sixth conductive layer 344 in the vertical direction DR3 may be formed unevenly. For instance, both sidewalls of the sixth conductive layer 344 in the first horizontal direction DR1 may be in contact with the first upper interlayer insulating layer 320.

For example, the upper surface of the sixth conductive layer 344 may be formed on the same plane as the upper surface of the first upper interlayer insulating layer 320. For example, the upper surface of the sixth conductive layer 344 may be in contact with the second upper interlayer insulating layer 350. For example, each sidewall of the second wiring barrier layer 341, the fourth conductive layer 342, the fifth conductive layer 343, and the sixth conductive layer 344 in the first horizontal direction DR1, which are in contact with the first upper interlayer insulating layer 320, may have a continuously sloped profile. For example, the width of the upper surface of the sixth conductive layer 344 in the first horizontal direction DR1 may be smaller than the width of the upper surface of the fourth conductive layer 342 in the first horizontal direction DR1. For example, the sixth conductive layer 344 may include the same metal as the metal included in the fourth conductive layer 342.

In some embodiments, the first wiring barrier layer 141 and the second wiring barrier layer 341 may not be provided. That is, the lower surface of the first conductive layer 142 may be in contact with the upper surface of the first contact 110 and the lower interlayer insulating layer 300, and the lower surface of the fourth conductive layer 342 may be in contact with the upper surface of the second contact 310 and the lower interlayer insulating layer 300. In embodiments, at least one of the first conductive layer 142 and the third conductive layer 144 may include nitrogen atoms, and at least one of the fourth conductive layer 342 and the sixth conductive layer 344 may also include nitrogen atoms.

In yet another embodiment, the second conductive layer 143 and the fifth conductive layer 343 may not be provided. That is, the third conductive layer 144 may be in contact with the upper surface of the first conductive layer 142, and the sixth conductive layer 344 may be in contact with the upper surface of the fourth conductive layer 342. For example, even if the second conductive layer 143 and the fifth conductive layer 343 are not provided, at least one of the first conductive layer 142 and the third conductive layer 144 may include nitrogen atoms, and at least one of the fourth conductive layer 342 and the sixth conductive layer 344 may include nitrogen atoms. The description of the distribution and the relative difference in the concentration of nitrogen atoms in the fourth conductive layer 342 and the sixth conductive layer 344 is similar to the description provided in FIGS. 1 to 3 regarding the distribution and relative difference in the concentration of nitrogen atoms in the first conductive layer 142 and the third conductive layer 144. Accordingly, a detailed explanation will be omitted.

Hereinafter, a method for fabricating a semiconductor device according to several embodiments of the present disclosure will be described with reference to FIGS. 29 to 36. The description will focus on differences from the method for fabricating the semiconductor device shown in FIGS. 4 to 17.

FIGS. 30 to 36 are intermediate stage diagrams for explaining a method for fabricating a semiconductor device according to several embodiments of the present disclosure.

Referring to FIG. 30, the first contact trench 110T and the second contact trench 310T may be formed in the lower interlayer insulating layer 300, which includes the first upper surface 300u1 and the second upper surface 300u2 having a step difference. The first contact trench 110T may be formed to recess into the lower interlayer insulating layer 300 from the first upper surface 300u1 of the lower interlayer insulating layer 300. The second contact trench 310T may be formed to recess into the lower interlayer insulating layer 300 from the second upper surface 300u2 of the lower interlayer insulating layer 300. The second upper surface 300u2 of the lower interlayer insulating layer 300 may be formed to be lower than the first upper surface 300u1 of the lower interlayer insulating layer 300. The second contact trench 310T may be spaced apart from the first contact trench 110T in the first horizontal direction DR1. Subsequently, the first contact 110 may be formed in the first contact trench 110T, and the second contact 310 may be formed in the second contact trench 310T.

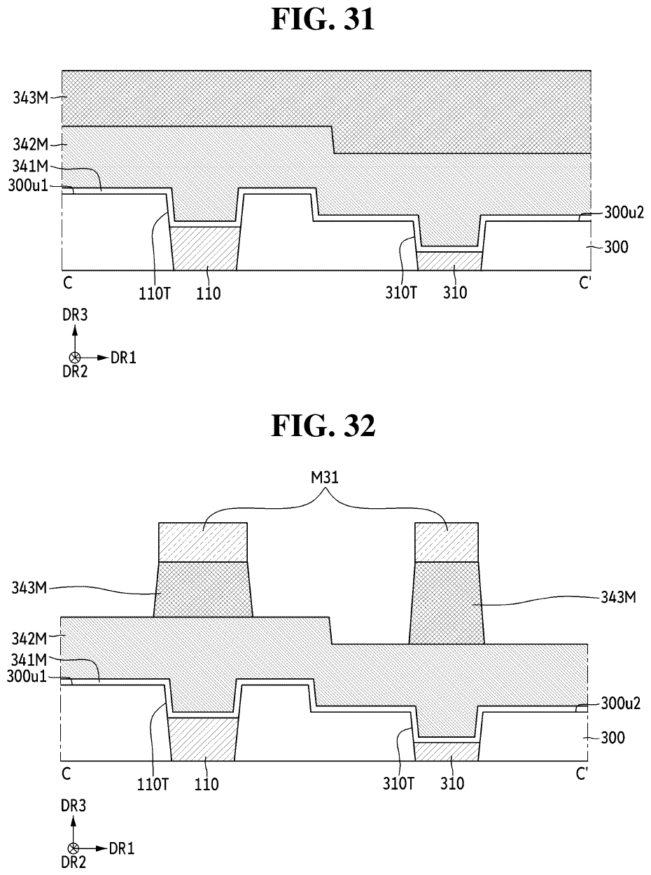

Referring to FIG. 31, the wiring barrier material layer 341M, the first conductive material layer 342M, and the second conductive material layer 343M may be sequentially formed on the upper surface of the first contact 110, the upper surface of the second contact 310, and the upper surface of the lower interlayer insulating layer 300.

Referring to FIG. 32, the first mask pattern M31 may be formed on the upper surface of the second conductive material layer 343M. For example, the first mask pattern M31 may overlap the first contact 110 and the second contact 310 in the vertical direction DR3. For example, the first mask pattern M31 may extend in the second horizontal direction DR2. Next, using the first mask pattern M31 as a mask, a portion of the second conductive material layer 343M may be etched.

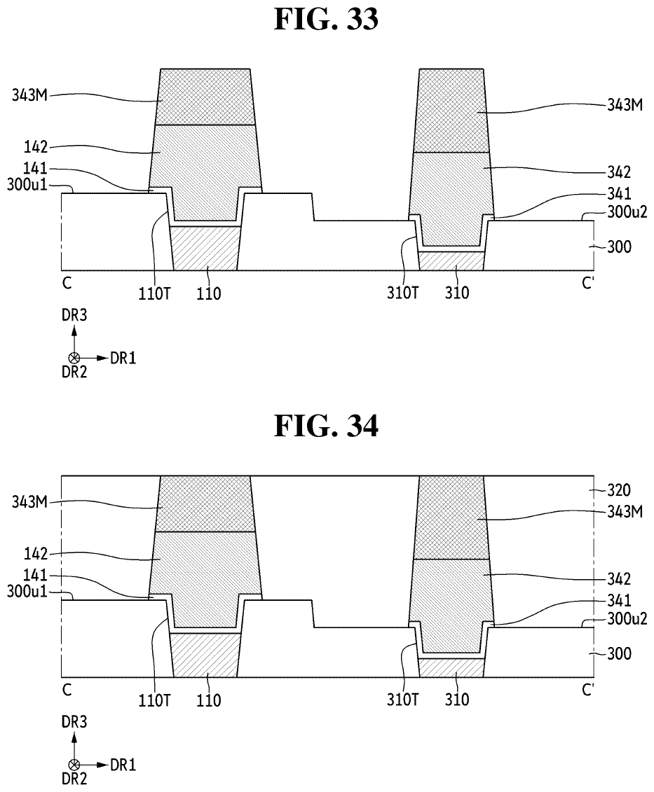

Referring to FIG. 33, the first mask pattern M31 (see FIG. 32) may be removed. Then, using the remaining second conductive material layer 343M as a mask, a portion of the first conductive material layer 342M (see FIG. 32) and a portion of the wiring barrier material layer 341M (see FIG. 32) may be etched. After this etching process is completed, the portion of the first conductive material layer 342M (see FIG. 32) remaining on the upper surface of the first contact 110 may be defined as the first conductive layer 142, and the portion of the first conductive material layer 342M (see FIG. 32) remaining on the upper surface of the second contact 310 may be defined as the fourth conductive layer 342. In addition, after the etching process is completed, the portion of the wiring barrier material layer 341M (see FIG. 32) remaining on the upper surface of the first contact 110 may be defined as the first wiring barrier layer 141, the portion of the wiring barrier material layer 341M (see FIG. 32) remaining on the upper surface of the second contact 310 may be defined as the second wiring barrier layer 341.

For example, the sidewalls of the second conductive material layer 343M, the first conductive layer 142, and the first wiring barrier layer 141 remaining on the upper surface of the first contact 110, in the first horizontal direction DR1, may have a continuously sloped profile. Also, the sidewalls of each of the second conductive material layer 343M, the fourth conductive layer 342, and the second wiring barrier layer 341 remaining on the upper surface of the second contact 310 in the first horizontal direction DR1 may have a continuously sloped profile.

Referring to FIG. 34, the first upper interlayer insulating layer 320 may be formed to cover the second conductive material layer 343M, the first conductive layer 142, the first wiring barrier layer 141, the fourth conductive layer 342, and the second wiring barrier layer 341 on the upper surface of the lower interlayer insulating layer 300. Subsequently, a planarization process may be performed such that the upper surface of the second conductive material layer 343M is exposed.

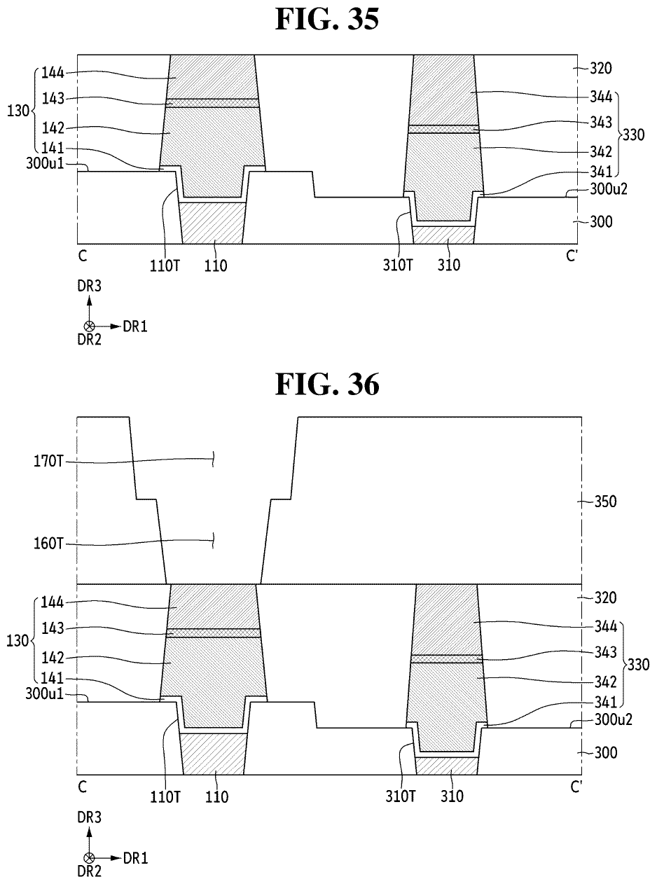

Referring to FIG. 35, an annealing process may be performed to remove nitrogen from a portion of the second conductive material layer 343M (see FIG. 34). For example, on the upper surface of the first contact 110, the portion of the second conductive material layer 343M (see FIG. 34) from which nitrogen has been removed from the second conductive material layer 343M (see FIG. 34) may be defined as the third conductive layer 144. In addition, on the upper surface of the second contact 310, the portion of the second conductive material layer 343M (see FIG. 34) from which nitrogen has been removed from the second conductive material layer 343M (see FIG. 34) may be defined as the sixth conductive layer 344.

For example, on the upper surface of the first contact 110, the remaining portion of the second conductive material layer 343M (see FIG. 34) in which nitrogen has not been removed from the second conductive material layer 343M (see FIG. 34) may be defined as the second conductive layer 143. In addition, on the upper surface of the second contact 310, the remaining portion of the second conductive material layer 343M (see FIG. 34) in which nitrogen has not been removed from the second conductive material layer 343M (see FIG. 34) may be defined as the fifth conductive layer 443.

For example, in the first horizontal direction DR1, the sidewalls of the second wiring barrier layer 341, the fourth conductive layer 342, the fifth conductive layer 343, and the sixth conductive layer 344, each of which is in contact with the first upper interlayer insulating layer 320, may have a continuously sloped profile. For example, the upper surfaces of the third conductive layer 144, the sixth conductive layer 344, and the first upper interlayer insulating layer 320 may be formed on the same plane. For example, the thickness of the sixth conductive layer 344 in the vertical direction DR3 may be greater than the thickness of the third conductive layer 144 in the vertical direction DR3.

Referring to FIG. 36, the second upper interlayer insulating layer 350 may be formed on the upper surfaces of the first upper interlayer insulating layer 320, the third conductive layer 144, and the sixth conductive layer 344. Subsequently, the via trench 160T and the upper wiring trench 170T may be formed in the second upper interlayer insulating layer 350. For example, the via trench 160T may be formed on the upper surface of the third conductive layer 144. The upper wiring trench 170T may be formed above the via trench 160T. For example, the via trench 160T and the upper wiring trench 170T may be formed through the same fabrication process. However, the present disclosure is not limited thereto.

Referring to FIG. 29, the via 160 may be formed in the via trench 160T (see FIG. 36), and the upper wiring pattern 170 may be formed in the upper wiring trench 170T (see FIG. 36). For example, the via 160 may be in contact with the upper surface of the third conductive layer 144. The upper wiring pattern 170 may be in contact with the upper surface of the via 160. For example, the via 160 and the upper wiring pattern 170 may be formed integrally. Through such a fabrication process, the semiconductor device shown in FIG. 29 may be fabricated.

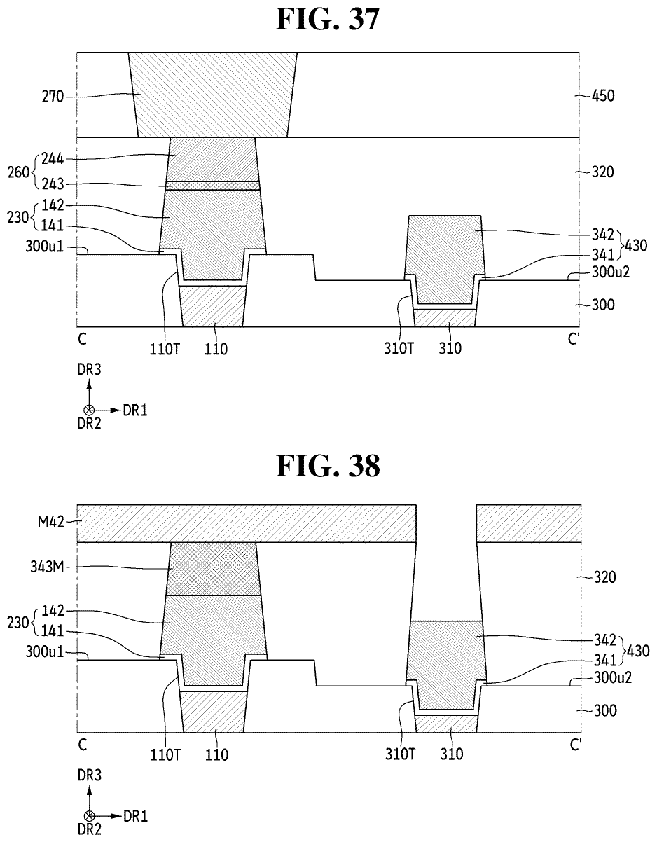

Hereinafter, a semiconductor device according to another embodiment of the present disclosure will be described with reference to FIG. 37. The description will focus on differences from the semiconductor devices shown in FIGS. 18 and 19 and FIG. 29, respectively.

FIG. 37 is a cross-sectional view for explaining a semiconductor device according to embodiments of the present disclosure.

Referring to FIG. 37, the semiconductor device according to another embodiment of the present disclosure may include the second lower wiring pattern 430 including the second wiring barrier layer 341 and the fourth conductive layer 342.

For example, the second upper interlayer insulating layer 450 may be disposed on the upper surface of the first upper interlayer insulating layer 320. The upper wiring pattern 270 may be disposed in the second upper interlayer insulating layer 450. For example, the upper wiring pattern 270 may be electrically connected to the first lower wiring pattern 230 through the via 260. For example, the first lower wiring pattern 230 may include the first wiring barrier layer 141 and the first conductive layer 142. The first lower wiring pattern 230 may extend in the second horizontal direction DR2. That is, the first wiring barrier layer 141 and the first conductive layer 142 may each extend in the second horizontal direction DR2. For example, the via 260 may include the second conductive layer 243 and the third conductive layer 244.

For example, the upper surface of the lower interlayer insulating layer 300 may include the first upper surface 300u1 adjacent to the first contact trench 110T and the second upper surface 300u2 adjacent to the second contact trench 310T. For example, the second upper surface 300u2 of the lower interlayer insulating layer 300 may be formed to be lower than the first upper surface 300u1 of the lower interlayer insulating layer 300. For example, the second wiring barrier layer 341 may be disposed on the upper surface of the second contact 310 and on the second upper surface 300u2 of the lower interlayer insulating layer 300. In addition, the second wiring barrier layer 341 may be disposed along the sidewalls of the second contact trench 310T on the upper surface of the second contact 310. The fourth conductive layer 342 may be disposed on the upper surface of the second wiring barrier layer 341. For example, the second wiring barrier layer 341 and the fourth conductive layer 342 may each extend in the second horizontal direction DR2. For example, the upper surface of the fourth conductive layer 342 may be in contact with the first upper interlayer insulating layer 320. For example, the upper surface of the fourth conductive layer 342 may be formed to be lower than the upper surface of the first conductive layer 142.

In some embodiments, each of the first wiring barrier layer 141 and the second wiring barrier layer 341 may not be provided. That is, the lower surface of the first conductive layer 142 may be in contact with the upper surface of the first contact 110 and the lower interlayer insulating layer 300, and the lower surface of the fourth conductive layer 342 may be in contact with the upper surface of the second contact 310 and the lower interlayer insulating layer 300. In some embodiments, at least one of the first conductive layer 142 and the third conductive layer 244 may include nitrogen atoms, and the fourth conductive layer 342 may also include nitrogen atoms.

In some embodiments, the second conductive layer 143 may not be provided. That is, the third conductive layer 244 may be in contact with the upper surface of the first conductive layer 142. For example, even if the second conductive layer 243 is not provided, at least one of the first conductive layer 142 and the third conductive layer 244 may include nitrogen atoms, and the fourth conductive layer 342 may include nitrogen atoms. For example, if the fourth conductive layer 342 contains nitrogen atoms, the concentration of nitrogen atoms in the fourth conductive layer 342 may increase toward the upper surface of the fourth conductive layer 342 from the lower surface of the fourth conductive layer 342. The description of the distribution and the relative difference in the concentration of nitrogen atoms in the first conductive layer 142 and the third conductive layer 244 is the same as that described in FIGS. 1 to 3, and therefore, a detailed description will be omitted.

Hereinafter, a method for fabricating a semiconductor device according to another embodiment of the present disclosure will be described with reference to FIGS. 37 to 41. The description will focus on differences from the method for fabricating the semiconductor device shown in FIGS. 30 to 36.

FIGS. 38 to 41 are intermediate stage diagrams for explaining a method for fabricating a semiconductor device according to another embodiment of the present disclosure.

Referring to FIG. 38, after performing the fabrication process shown in FIG. 30 to 34, a second mask pattern M42 may be formed on the upper surface of the remaining second conductive material layer 343M and the upper surface of the first upper interlayer insulating layer 320. The second mask pattern M42 may overlap the first contact 110 in the vertical direction DR3. For example, the second mask pattern M42 may expose the upper surface of the second conductive material layer 343M formed on the upper surface of the second contact 310.

Subsequently, using the second mask pattern M42 as a mask, the second conductive material layer 343M formed on the upper surface of the second contact 310 may be etched. Through this etching process, the upper surface of the fourth conductive layer 342 may be exposed. After the etching process is completed, the remaining second wiring barrier layer 341 and fourth conductive layer 342 may be defined as the second lower wiring pattern 430.

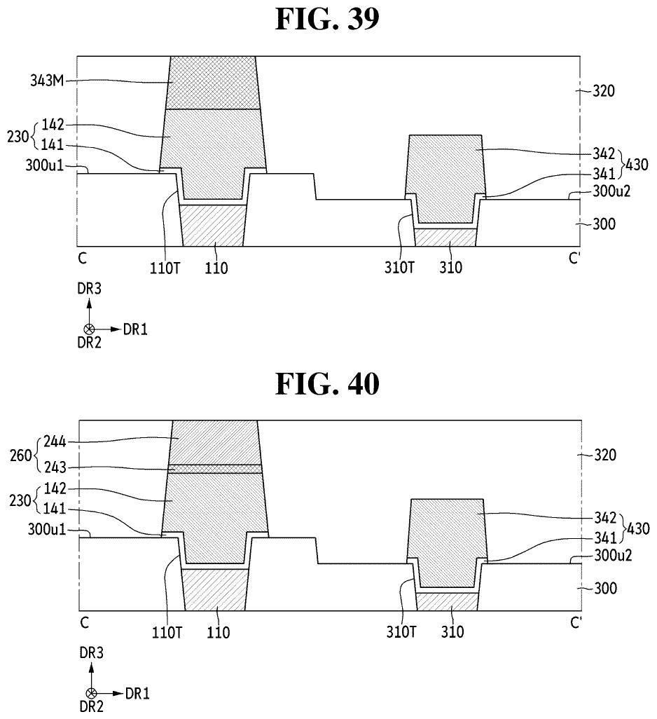

Referring to FIG. 39, the second mask pattern M42 (see FIG. 38) may be removed. Subsequently, the first upper interlayer insulating layer 320 may be additionally formed on the upper surface of the fourth conductive layer 342. For example, the first upper interlayer insulating layer 320 may also be additionally formed on the upper surface of the second conductive material layer 343M. Then, a planarization process may be performed so that the upper surface of the second conductive material layer 343M is exposed.

Referring to FIG. 40, an annealing process may be performed to remove nitrogen from a portion of the second conductive material layer 343M (see FIG. 39). For example, the portion of the second conductive material layer 343M (see FIG. 39) in which nitrogen has been removed from the second conductive material layer 343M (see FIG. 39) may be defined as the third conductive layer 244. In addition, the remaining portion of the second conductive material layer 343M (see FIG. 39) in which nitrogen has not been removed from the second conductive material layer 343M (see FIG. 39) may be defined as the second conductive layer 243. For example, the second conductive layer 243 and the third conductive layer 244 may be defined as the via 260.

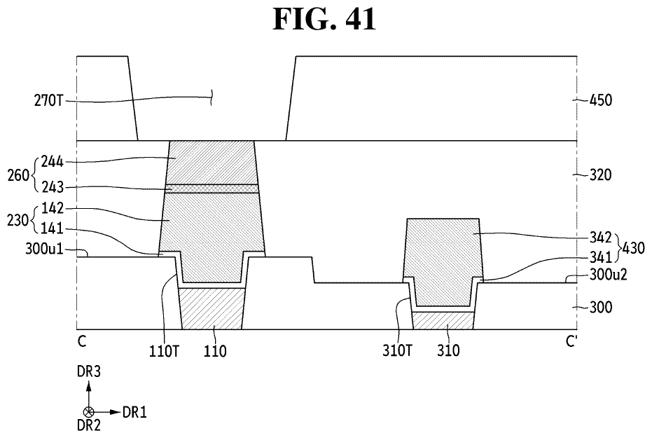

Referring to FIG. 41, the second upper interlayer insulating layer 450 may be formed on the upper surface of the first upper interlayer insulating layer 320 and the upper surface of the third conductive layer 244. Then, the upper wiring trench 270T may be formed in the second upper interlayer insulating layer 450. For example, the upper wiring trench 270T may be formed on the upper surface of the third conductive layer 244. The upper surface of the third conductive layer 244 may be exposed through the bottom surface of the upper wiring trench 270T. For example, the upper wiring trench 270T may extend in the second horizontal direction DR2.

Referring to FIG. 37, the upper wiring pattern 270 may be formed in the upper wiring trench 270T (see FIG. 41). For example, the upper wiring pattern 270 may be in contact with the upper surface of the third conductive layer 244. Through such a fabrication process, the semiconductor device shown in FIG. 37 may be fabricated.

According to some embodiments of the present disclosure, there is provided a method for fabricating a semiconductor device, comprising forming a contact in a lower interlayer insulating layer, forming a first conductive material layer on an upper surface of the lower interlayer insulating layer and an upper surface of the contact, the first conductive material layer including a metal, forming a second conductive material layer on an upper surface of the first conductive material layer, the second conductive material layer including a metal nitride containing the metal, etching a portion of the second conductive material layer, etching a portion of the first conductive material layer using the remaining portion of the second conductive material layer as a mask, wherein a remaining portion of the first conductive material layer is defined as a first conductive layer, forming a first upper interlayer insulating layer covering sidewall of each of the first conductive layer and the second conductive material layer in a first horizontal direction, and forming a third conductive layer including the metal by removing nitrogen from a portion of the second conductive material layer, wherein a remaining portion of the second conductive material layer from which nitrogen is not removed is defined as a second conductive layer, wherein the sidewalls of the first to third conductive layers in the first horizontal direction, which are in contact with the first upper interlayer insulating layer, have a continuously sloped profile.

According to some embodiments of the present disclosure, there is provided a method for fabricating a semiconductor device, comprising wherein the first to third conductive layers extend in a second horizontal direction different from the first horizontal direction.

According to some embodiments of the present disclosure, there is provided a method for fabricating a semiconductor device, comprising before forming the third conductive layer, forming a mask pattern on an upper surface of the remaining portion of the second conductive material layer and on an upper surface of the first upper interlayer insulating layer, exposing a sidewall of the second conductive material layer in a second horizontal direction different from the first horizontal direction by etching a portion of the second conductive material layer using the mask pattern as a mask, and forming the first upper interlayer insulating layer additionally to cover the sidewall of the second conductive material layer in the second horizontal direction.

According to some embodiments of the present disclosure, there is provided a method for fabricating a semiconductor device, comprising after forming the third conductive layer, forming a second upper interlayer insulating layer on an upper surface of the first upper interlayer insulating layer and an upper surface of the third conductive layer, and forming a via and an upper wiring pattern on the upper surface of the third conductive layer in the second upper interlayer insulating layer, wherein the via is in contact with the upper surface of the third conductive layer, the upper wiring pattern is in contact with an upper surface of the via, and the via and the upper wiring pattern are integrally formed.

According to some embodiments of the present disclosure, there is provided a method for fabricating a semiconductor device, comprising after forming the third conductive layer, forming a second upper interlayer insulating layer on an upper surface of the first upper interlayer insulating layer and an upper surface of the third conductive layer, and forming an upper wiring pattern being in contact with the upper surface of the third conductive layer in the second upper interlayer insulating layer.

Although the embodiments of the present disclosure have been described with reference to the accompanying drawings, it will be understood that the present disclosure is not limited to the above-described embodiments, and may be implemented in various other forms. Those skilled in the art to which the present disclosure pertains will understand that the present disclosure may be implemented in other specific forms without changing the technical idea or essential features. Accordingly, the embodiments described above should be understood to be exemplary in all respects and not restrictive.

What is claimed is:

1. A semiconductor device comprising:
a lower interlayer insulating layer;
a first contact trench formed in the lower interlayer insulating layer;
a first contact disposed in the first contact trench;
a first conductive layer disposed on an upper surface of the first contact, a width of the first conductive layer in a first horizontal direction greater than a width of the first contact trench in the first horizontal direction, the first conductive layer extending in a second horizontal direction different from the first horizontal direction, the first conductive layer including a metal;
a second conductive layer being in contact with an upper surface of the first conductive layer, the second conductive layer including a metal nitride containing the metal;
a third conductive layer being in contact with an upper surface of the second conductive layer, the third conductive layer including the metal; and
a first upper interlayer insulating layer disposed on an upper surface of the lower interlayer insulating layer, the first upper interlayer insulating layer being in contact with sidewalls of the first to third conductive layers in the first horizontal direction,
wherein the sidewalls of the first to third conductive layers in the first horizontal direction, which are in contact with the first upper interlayer insulating layer, have a continuously sloped profile.

2. The semiconductor device of claim 1, wherein a width of an upper surface of the third conductive layer in the first horizontal direction is smaller than a width of the upper surface of the first conductive layer in the first horizontal direction.

3. The semiconductor device of claim 1, wherein the first upper interlayer insulating layer is in contact with the upper surface of the lower interlayer insulating layer.

4. The semiconductor device of claim 1, wherein at least a portion of the first conductive layer is disposed in the first contact trench.

5. The semiconductor device of claim 1, wherein the metal is ruthenium (Ru), and the metal nitride is ruthenium nitride (RuN).

6. The semiconductor device of claim 1, wherein each of the second conductive layer and the third conductive layer extends in the second horizontal direction.

7. The semiconductor device of claim 1, wherein the upper surface of the first conductive layer is in contact with the first upper interlayer insulating layer on the sidewall of each of the second conductive layer and the third conductive layer in the second horizontal direction.

8. The semiconductor device of claim 1, further comprising:
a second upper interlayer insulating layer disposed on an upper surface of the first upper interlayer insulating layer,
a via disposed in the second upper interlayer insulating layer, the via being in contact with an upper surface of the third conductive layer, and
an upper wiring pattern disposed in the second upper interlayer insulating layer, the upper wiring pattern being in contact with an upper surface of the via, the upper wiring pattern integrally formed with the via, the upper wiring pattern extending in the second horizontal direction.

9. The semiconductor device of claim 1, further comprising:
a second upper interlayer insulating layer disposed on an upper surface of the first upper interlayer insulating layer; and
an upper wiring pattern disposed in the second upper interlayer insulating layer, the upper wiring pattern being in contact with an upper surface of the third conductive layer, the upper wiring pattern extending in the second horizontal direction.

10. The semiconductor device of claim 1, further comprising:
a second contact trench formed in the lower interlayer insulating layer, the second contact trench spaced apart from the first contact trench in the first horizontal direction;
a second contact disposed in the second contact trench; and
a fourth conductive layer disposed on an upper surface of the second contact, the fourth conductive layer spaced apart from the first conductive layer in the first horizontal direction, the fourth conductive layer extending in the second horizontal direction, the fourth conductive layer including the metal.
wherein an upper surface of the fourth conductive layer is lower than the upper surface of the first conductive layer.

11. The semiconductor device according to claim 10, wherein the upper surface of the lower interlayer insulating layer includes a first upper surface adjacent to the first contact trench and a second upper surface adjacent to the second contact trench, and
wherein the second upper surface of the lower interlayer insulating layer is lower than the first upper surface of the lower interlayer insulating layer.

12. The semiconductor device of claim 10, further comprising:
a fifth conductive layer being in contact with the upper surface of the fourth conductive layer, the fifth conductive layer including the metal nitride; and
a sixth conductive layer being in contact with an upper surface of the fifth conductive layer, the sixth conductive layer including the metal, an upper surface of the sixth conductive layer formed on the same plane as an upper surface of the third conductive layer,
wherein sidewalls of the fourth to sixth conductive layers in the first horizontal direction have a continuously sloped profile.

13. A semiconductor device comprising:
a first contact;
a first conductive layer disposed on an upper surface of the first contact, the first conductive layer including a metal;
a second conductive layer being in contact with an upper surface of the first conductive layer, the second conductive layer including a metal nitride containing the metal;
a third conductive layer being in contact with an upper surface of the second conductive layer, the third conductive layer including the metal;
a first upper interlayer insulating layer being in contact with sidewalls of the first to third conductive layers in a first horizontal direction;
a second upper interlayer insulating layer disposed on an upper surface of the first upper interlayer insulating layer; and
an upper wiring pattern disposed on an upper surface of the third conductive layer, the upper wiring pattern extending in a second horizontal direction different from the first horizontal direction, the upper wiring pattern electrically connected to the third conductive layer,
wherein a width of the upper surface of the third conductive layer in the first horizontal direction is smaller than a width of the upper surface of the first conductive layer in the first horizontal direction.

14. The semiconductor device according to claim 13, wherein the sidewalls of the first to third conductive layers in the first horizontal direction, which are in contact with the first interlayer insulating layer, have a continuously sloped profile.

15. The semiconductor device according to claim 13, wherein the upper surface of the third conductive layer is formed on the same plane as the upper surface of the first upper interlayer insulating layer.

16. The semiconductor device according to claim 13, further comprising:
a wiring barrier layer disposed between the upper surface of the first contact and the first conductive layer.

17. The semiconductor device according to claim 13, wherein each of the second conductive layer and the third conductive layer extends in the second horizontal direction.

18. The semiconductor device according to claim 13, further comprising:
a second contact spaced apart from the first contact in the first horizontal direction, and
a fourth conductive layer disposed on an upper surface of the second contact, the fourth conductive layer spaced apart from the first conductive layer in the first horizontal direction, the fourth conductive layer extending in the second horizontal direction, the fourth conductive layer including the metal,
wherein an upper surface of the fourth conductive layer is lower than the upper surface of the first conductive layer.

19. The semiconductor device according to claim 18, further comprising:
a fifth conductive layer being in contact with the upper surface of the fourth conductive layer, the fifth conductive layer including the metal nitride; and
a sixth conductive layer being in contact with an upper surface of the fifth conductive layer, the sixth conductive layer including the metal, an upper surface of the sixth conductive layer formed on the same plane as an upper surface of the third conductive layer,
wherein sidewalls of the fourth to sixth conductive layers in the first horizontal direction have a continuously sloped profile.

20. A semiconductor device comprising:
a lower interlayer insulating layer;
a contact trench formed in the lower interlayer insulating layer;
a contact disposed in the contact trench,
a wiring barrier layer being in contact with an upper surface of the contact;
a first conductive layer being in contact with an upper surface of the wiring barrier layer, a width of the first conductive layer in a first horizontal direction greater than a width of the contact trench in the first horizontal direction, the first conductive layer extending in a second horizontal direction different from the first horizontal direction, the first conductive layer including ruthenium (Ru);
a second conductive layer being in contact with an upper surface of the first conductive layer, the second conductive layer including ruthenium nitride (RuN), the second conductive layer extending in the second horizontal direction;
a third conductive layer being in contact with an upper surface of the second conductive layer, the third conductive layer including ruthenium (Ru), the third conductive layer extending in the second horizontal direction;
a first upper interlayer insulating layer disposed on an upper surface of the lower interlayer insulating layer, the first upper interlayer insulating layer being in contact with sidewalls of the first to third conductive layers in the first horizontal direction, an upper surface of the first upper interlayer insulating layer formed on the same plane as an upper surface of the third conductive layer,
a second upper interlayer insulating layer disposed on the upper surface of the first upper interlayer insulating layer;
a via disposed in the second upper interlayer insulating layer, the via being in contact with the upper surface of the third conductive layer; and
an upper wiring pattern disposed in the second upper interlayer insulating layer, the upper wiring pattern being in contact with an upper surface of the via, the upper wiring pattern formed integrally with the via, the upper wiring pattern extending in the second horizontal direction,
wherein the sidewalls of the first to third conductive layers in the first horizontal direction, which are in contact with the first upper interlayer insulating layer, have a continuously sloped profile, and
wherein a width of the upper surface of the third conductive layer in the first horizontal direction is smaller than a width of the upper surface of the first conductive layer in the first horizontal direction.
